(19) United States
(12) Patent Application Publication
(10) Pub. No.: US 2007/0010070 A1
(43) Pub. Date: Jan. 11, 2007

(54) FABRICATION OF STRAINED SEMICONDUCTOR-ON-INSULATOR (SSOI) STRUCTURES BY USING STRAINED INSULATING LAYERS

(75) Inventors: Michael P. Belyansky, Bethel, CT (US); Meikei Ieong, Wappingers Falls, NY (US); Haizhou Yin, Beacon, NY (US)

Correspondence Address: SCULLY, SCOTT, MURPHY & PRESSNER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/160,668

(22) Filed: Jul. 5, 2005

(51) Int. Cl. H01L 21/20; H01L 21/36

(52) U.S. Cl. 438/478

(57) ABSTRACT

The present invention relates to a method for forming one or more strained semiconductor-on-insulator structures, by first forming a precursor structure that contains an upper layer of unstrained semiconductor material and a lower layer of strained insulating material supported by a semiconductor substrate, and then patterning the upper layer of unstrained semiconductor material and the lower layer of strained insulating material to form one or more islands that each contain an unstrained semiconductor material layer over a strained insulating material layer. Relaxation of the strained insulating material layers in such islands applies strain to the unstrained semiconductor material layers, thus forming one or more strained semiconductor-on-insulator structures. The method of the present invention uses a strained insulating material layer to apply strain to an unstrained semiconductor material layer, and can therefore completely avoid usage of any additional strain-inducing layer in forming strained semiconductor material.

### BACKGROUND OF THE INVENTION

Today's integrated circuits include a vast number of metal-oxide-semiconductor field effect transistors (MOSFETs). Device scaling has been the key to drive device performance enhancement. However, as the devices are being scaled down, the technology becomes more complex, and changes in device structures and new fabrication methods are needed to maintain the expected performance enhancement from one generation of devices to the next.

Several avenues are being explored for maintaining the performance enhancement. Among these is the use of strained semiconductor materials. For example, in silicon, electron mobility can be enhanced when the silicon film is under tensile strain, while the hole mobility can be enhanced when the film is under compressive strain. Therefore, strained silicon can be advantageously used in CMOS circuits to boost the speed of such circuits.

The strained Si layer is typically formed by epitaxially growing silicon over a thick, relaxed SiGe buffer layer. The lattice constant of germanium is about 4.2% greater than that of silicon, and the lattice constant of a silicon-germanium alloy is linear with respect to its germanium concentration. As a result, the lattice constant of a SiGe alloy with twenty atomic percent of germanium is about 0.8% greater than the lattice constant of silicon. Epitaxial growth of silicon on such a SiGe buffer layer will yield a silicon layer under tensile strain, with the underlying SiGe buffer layer being essentially unstrained, or “relaxed.”

The use of such a strain-inducing SiGe layer has several inherent disadvantages: (1) formation of relaxed SiGe buffer layer relies on defect formation, and consequentially, the SiGe material has a high defect density, which propagates into the silicon layer and poses significant challenges for device applications, such as control of leakage current and device yield, and (2) the presence of the SiGe layer in the device structure creates processing issues, such as deleterious diffusion of germanium into the strained silicon layer, high resistance silicide and altered dopant diffusion.

U.S. Pat. No. 6,603,156 issued to Rim describes a method for forming a strained silicon-on-insulator structure, by first growing a strained silicon layer on a strain-inducing SiGe layer to form a multilayer structure, bonding such a multilayer structure to a substrate containing an insulating layer thereon, in such a manner that the insulating is between the strained silicon layer and the substrate, and then removing the strain-inducing SiGe layer to form a strained silicon-on-insulator structure that is free of the SiGe layer.

However, the aforementioned prior art method requires formation of thick, relaxed SiGe layer, which significantly increases the processing complexity and manufacturing cost. Further, the strained silicon layer formed by the method described by the '156 patent is still subject to defects stemming from threading dislocations in the strain-inducing SiGe layer.

### SUMMARY OF THE INVENTION

The present invention provides a method for forming a strained semiconductor-on-insulator (SSOI) structure, by using a strained insulating layer to apply strain to an unstrained semiconductor layer.

The method of the present invention does not require usage of any additional strain-inducing layer, and therefore avoids all the above-described disadvantages associated with conventional methods that employ additional strain-inducing layers.

In one aspect, the present invention relates to a method for forming one or more strained semiconductor-on-insulator structures, comprising the steps of:

forming a precursor structure comprising an upper layer of unstrained semiconductor material and a lower layer of strained insulating material supported by a semiconductor substrate; and

patterning the upper layer of unstrained semiconductor material and the lower layer of strained insulating material to form one or more islands that each comprise an unstrained semiconductor material layer over a strained insulating material layer, while relaxation of the strained insulating material layers in such islands applies strain to the unstrained semiconductor material layers, thereby forming one or more strained semiconductor-on-insulator structures.

The present invention in another aspect relates to a precursor structure, which comprises one or more islands supported by a semiconductor substrate, where each island comprises a semiconductor material layer overlaying a strained insulating material layer. Relaxation of the strained insulating material layers in said islands applies strain to the semiconductor material layers, thereby forming one or more strained semiconductor-on-insulator structures.

Other aspects, features and advantages of the invention will be more fully apparent from the ensuing disclosure and appended claims.

### BRIEF DESCRIPTION OF THE DRAWINGS

FIGS. 1A and 1B illustrate formation of an exemplary strained semiconductor-on-insulator structure by using a strained insulating material layer, according to one embodiment of the present invention.

FIGS. 2A-2D illustrate the processing steps for forming an exemplary strained semiconductor-on-insulator structure by using an insulating layer with in situ generated compressive stress, according to one embodiment of the present invention.

FIGS. 3A-3C illustrate the processing steps for forming an exemplary strained semiconductor-on-insulator structure by using a pre-formed compressively strained insulating layer, according to one embodiment of the present invention.

FIG. 4 shows the stress response curves of spin-on glass during high temperature annealing process at different temperatures and under different processing conditions.

### DETAILED DESCRIPTION OF THE INVENTION AND PREFERRED EMBODIMENTS THEREOF

The present invention employs a strained insulating material layer, which is an intrinsic part of the strained semiconductor-on-insulator structure to be formed, to apply strain on the semiconductor layer through elastic strain manipulation.

It has been found that various semiconductor processing steps, such as high temperature annealing, oxidation, and ion implantation, can cause rearrangement of micro-crystal structures and induce significant biaxial strain in insulating layers that comprise oxides and nitrides, and combinations thereof. For example, high temperature annealing process on one hand can generate compressive strain in silicon dioxide films, and on the other hand, it can introduce tensile strain in silicon nitride layers. Certain insulating materials, such as spin-on glass, may be strained either compressively or tensilely, depending on the specific processing conditions such as annealing temperature and ambient.

Conventional wisdom considered such strain in the insulating layers undesirable, and suggested various methods for removing such strain. For example, J. Camassel and A. Tiberj described a method for forming a multi-insulating layer structure that comprises alternating silicon dioxide and silicon nitride layers, so that the compressive strain in the silicon dioxide layers and the tensile strain in the silicon nitride layer cancel out with each other, and thereby forming a strain-free insulating structure (see J. Camassel and A. Tiberj, Strain Effects in Device Processing of Silicon-on-Insulator Materials, APPLIED SURFACE SCIENCE, vol. 212-213, pp. 742-748 (2003).

In contrast to the conventional wisdom, the present invention utilizes an insulating layer with intentionally induced strain therein to facilitate formation of a strained semiconductor-on-insulator (SSOI) structure.

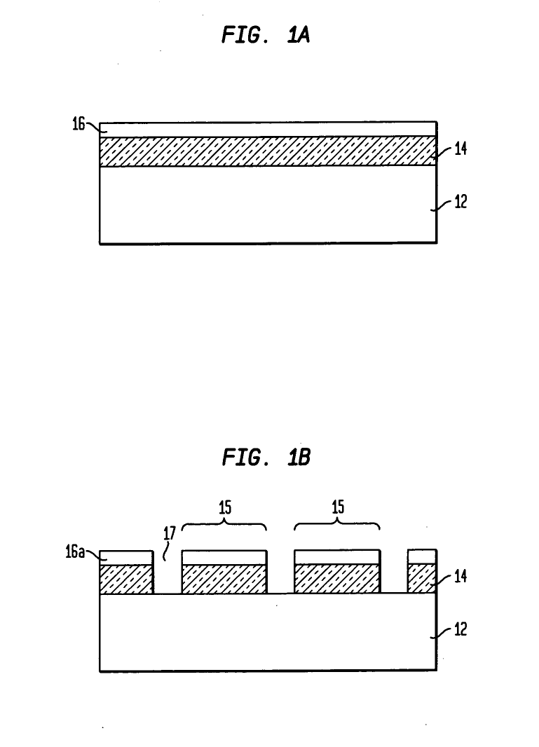

FIG. 1A illustratively shows a precursor structure for forming an exemplary SSOI structure, which comprises, from bottom to top, a semiconductor substrate 12, a thin layer of strained insulating material 14, and a thin layer of unstrained semiconductor material 16.

The semiconductor substrate 12 may comprise any suitable semiconductor materials, including, but not limited to, Si, SiC, SiGe, SiGeC, Ge, GaAs, InAs, InP, as well as other III-V or II-VI compound semiconductors. The semiconductor substrate 12 typically has a thickness that is sufficient to support the thin insulating material layer 14 and the thin semiconductor material layer 16 thereon.

The thin insulating material layer 14 may comprise any suitable insulating materials in which strain can be generated. For example, the insulating material layer 14 may contain one or more insulating oxides, insulating nitrides, insulating oxynitrides, and/or combinations thereof. In a preferred embodiment of the present invention, the insulating material layer 14 contains a spin-on dielectric material, more preferably spin-on glass, which has excellent thermal stability and little or no impurities. In another preferred embodiment of the present invention, the insulating material layer 14 contains highly strained silicon nitride, which has good thermal conductivity and is particularly useful for power device applications where thermal dissipation is required. The thickness of the insulating layer 14 may vary from about 50 nm to about 1 μm, and more preferably from about 100 nm to about 1 μm, depending on the specific requirements of the device structure to be formed.

The upper unstrained semiconductor material layer 16 may comprise any semiconductor material suitable for forming the semiconductor-on-insulator structure, including, but not limited to Si, Ge, SiGe, SiGeC, SiC, GaAs, InAs, InP, as well as other III-V or II-VI compound semiconductors. The thickness of the upper unstrained semiconductor layer 16 may vary depending on its specific applications. Preferably, the upper unstrained semiconductor layer 16 has a thickness from about 10 to about 1000 nm. The upper semiconductor layer 16 can also be subsequently thinned by oxidation and wet etching to achieve any desired small thickness to provide a thin semiconductor-on-insulator structure.

The precursor structure of FIG. 1A can be formed by a wafer bonding process. For example, such a precursor structure may be formed by first providing a layer of pre-strained insulating material, with intrinsic strain already generated therein, as supported by a semiconductor substrate, and then bonding an unstrained semiconductor material layer to an upper surface of such pre-strained insulating material layer.

Alternatively, the precursor structure may be formed by providing a layer of unstrained insulating material as supported by a semiconductor substrate, bonding an unstrained semiconductor material layer to an upper surface of such unstrained insulating material layer, and then in situ generating the desired strain in such unstrained insulating material layer.

Bonding of the upper unstrained semiconductor material layer 16 with the lower insulating material layer 14 is achieved by first bringing the two layers into intimate contact with other, optionally applying an external force to the contacted layers, and then heating the two contacted layers under conditions that are capable of bonding the two layers together. The heating step may be performed in the presence or absence of an external force. The heating step is typically performed in an inert ambient at a temperature from about 200° to about 1050° C. for a time period from about 2 to about 20 hours. More typically, the bonding is performed at a temperature from about 200° C. to about 400° C. for a time period from about 2 to about 20 hours. The term “inert ambient” is used in the present invention to denote an atmosphere in which an inert gas, such as He, Ar, N₂, Xe, Kr or a mixture thereof, is employed. A preferred ambient used during the bonding process is N₂. Other bonding conditions are also contemplated herein, including bonding that is performed at ambient temperature of from about 20° C. to about 40° C.

In situ generation of strain in an unstrained insulating material layer as described hereinabove can be carried out using one or more processing steps such as high temperature annealing, oxidation, and ion implantation.

For example, a high temperature annealing process can be used to create strain in the insulating material layer. The temperature range for the annealing process is typically from about 500° C. to about 1100° C., preferably from about 700° C. to about 1000° C., depending on the insulating materials being treated. The ambient can be changed to control the specific strain type in the insulating material layer. For spin-on glass insulating films, water vapor ambient generates compressive strain, while oxygen ambient generates tensile strain.

Subsequently, the upper unstrained semiconductor layer 16 and the lower strained insulating layer 14 of the precursor structure as shown in FIG. 1A are patterned into one or more island structures 15 over the substrate 12, which are isolated from each other by gap regions 17, as shown in FIG. 1B.

Formation of such island structures and provision of gap regions 17 therebetween allow inplane relaxation of the strained insulating material layer 14, i.e., the insulating layer 14 either expands (if the insulating layer 14 is compressively strained) or shrinks (if the insulating layer 14 is tensilely strained) laterally, which causes corresponding lateral expansion or shrinkage in the upper unstrained semiconductor layer 16, thus resulting in a strained semiconductor layer 16A with either tensile or compressive strain therein, as shown in FIG. 1B.

Patterning of the precursor structure of FIG. 1A can be carried out by a combination of lithography and etching steps. For example, a patterned mask can be formed by lithography on a predetermined portion of the precursor structure of FIG. 1A, so as to define a set of protected regions and a set of unprotected regions on the upper surface of such precursor structure. The patterned mask allows selective etching at the unprotected regions, so as to remove a portion of the upper unstrained semiconductor material layer 16 and a portion of the lower strained insulating material layer 14, thereby forming multiple isolated island structures 15, as shown in FIG. 1B. The selective etching may be performed utilizing a single etching process or multiple etching steps, including, but not limited to: a dry etching process such as reactive ion etching (RIE), ion beam etching, plasma etching or laser etching, or a wet etching process wherein a chemical etchant is employed, or any combination thereof. In a preferred embodiment of the present invention, reactive ion etching (RIE) is used for such selective etching. After etching, the mask is then removed from the structure by utilizing a conventional resist stripping process.

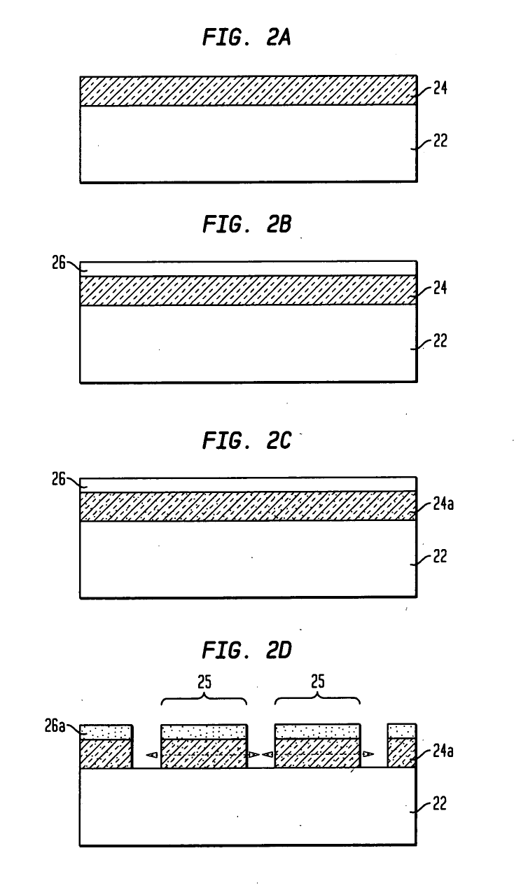

FIGS. 2A-2D illustrate a process in which an unstrained insulating material layer 24, as supported by a semiconductor substrate 22, is first provided, to which a thin unstrained semiconductor material layer 26 is bonded. The unstrained insulating material layer 24 is then treated in situ by one or more processing steps as described hereinabove, to form a compressively strained insulating material layer 24A. Subsequently, the unstrained semiconductor material layer 26 and the compressively strained insulating material layer 24A are patterned to form multiple isolated island structures 25, thereby allowing relaxation of the compressive strain in the insulating material layer 24A and generation of tensile strain in the originally unstrained semiconductor material layer 26. As a result, a strained semiconductor-on-insulator structure that contains a tensilely strained semiconductor material layer 26 A is formed.

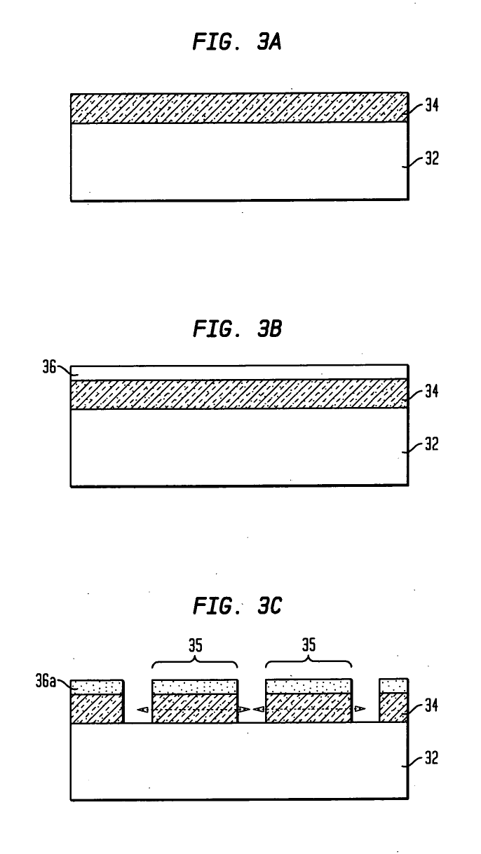

FIGS. 3A-3C illustrate a process in which a pre-strained insulating material layer 34, which contains strain therein and is supported by a semiconductor substrate 32, is provided. The pre-strained insulating material can be high-stress nitride formed by chemical vapor deposition, or spin-on insulator that is turned to high stress by thermal treatment. A thin unstrained semiconductor material layer 36 is bonded to an upper surface of the pre-strained insulating material layer 34. By patterning the unstrained semiconductor material layer 36 and the compressively pre-strained insulating material layer 34 to form multiple isolated island structures 35, the strain in the insulating material layer 34 can be relaxed, which generates opposite strain in the originally unstrained semiconductor material layer 36 and thereby forms a strained semiconductor-on-insulator structure with a strained semiconductor material layer 36A.

Preferably, the island structures as described hereinabove has an optimal dimension that allows generation of sufficient and uniform strain in the semiconductor material layer and avoids cracking of any structural layer due to overstress. For example, such island structures are preferably characterized by an average diameter ranging from about 100 nm to about 20 μm, and more preferably by an average diameter that is about 5 to 20 times of the thickness of the stressed insulating material layer.

Spin-on glass is a particular preferred insulating material for practicing the present invention, due to the stress characteristics of such material under different processing conditions.

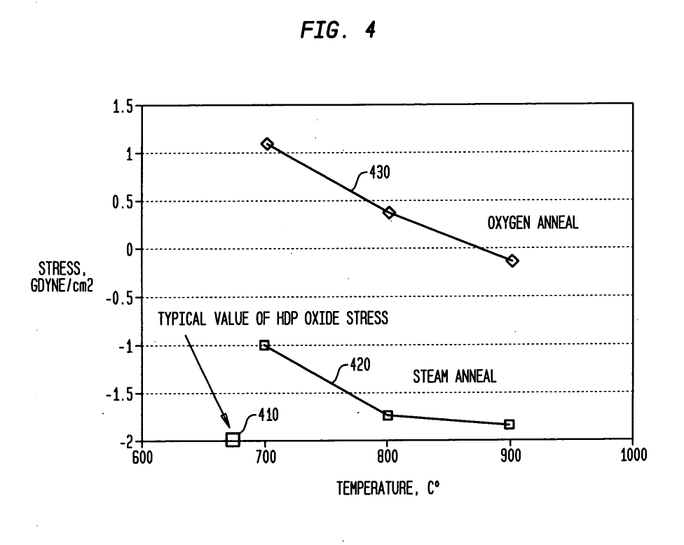

FIG. 4 shows two strain response curves for spin-on glass, one of which describes the strain responses of spin-on glass that was treated by an oxygen-based curing process, and the other of which describes the strain responses of spin-on glass that was treated by a water-vapor-based curing process, under varying processing temperatures ranging from about 700° C. to about 900° C. As indicated by such strain response curves, at a processing temperature of about 700° C., use of the oxygen-based curing process generates tensile strain in the spin-on glass, while use of the water-vapor-based curing process generates compressive strain instead. Therefore, spin-on glass can be used to apply either compressive strain (if the spin-on glass is tensilely strained) or tensile strain (if the spin-on glass is compressively strained) to the semiconductor material layer as desired, by using suitable curing techniques. Preferably, compressively strained spin-on glass is employed for forming tensilely strained silicon-on-insulator structures, in which the electron mobility is enhanced, and which is therefore particularly suitable for forming n-channel field effect transistors (FETs). On the other hand, tensilely strained spin-on glass is employed for forming compressively strained silicon-on-insulator structures, in which the hole mobility is enhanced, and which is therefore particularly suitable for forming p-channel field effect transistors (FETs).

The strained semiconductor-on-insulator structure as formed by the methods of the present invention can be widely used for fabricating various semiconductor device structures, including, but not limited to, metal-oxide-semiconductor field effect transistors (MOSFET), as well as integrated circuit, microprocessors and other electronic devices comprising strained semiconductor films, which are well known to those skilled in the art and can be readily modified to incorporate the strained semiconductor-on-insulator structure of the present invention, and therefore details concerning their fabrication are not provided herein.

It is noted that the drawings of the present invention are provided for illustrative purposes and are not drawn to scale.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A method for forming one or more strained semiconductor-on-insulator structures, comprising the steps of: forming a precursor structure comprising an upper layer of unstrained semiconductor material and a lower layer of strained insulating material supported by a semiconductor substrate; and patterning the upper layer of unstrained semiconductor material and the lower layer of strained insulating material to form one or more islands that each comprise an unstrained semiconductor material layer over a strained insulating material layer, wherein relaxation of the strained insulating material layers in said islands applies strain to the unstrained semiconductor material layers, thereby forming one or more strained semiconductor-on-insulator structures.

2. The method of claim 1, wherein said unstrained semiconductor material comprises one or more materials selected from the group consisting of Si, SiC, SiGe, SiGeC, Ge, GaAs, InAs, InP, III-V compound semiconductor materials, and II-VI compound semiconductor materials.

3. The method of claim 1, wherein said strained insulating material comprises one or more materials selected from the group consisting of insulating oxides, insulating nitrides, and combinations thereof.

4. The method of claim 1, wherein said strained insulating material comprises spin-on glass.

5. The method of claim 1, wherein the precursor structure is formed by: (a) providing a layer of pre-strained insulating material supported by a semiconductor substrate, and (b) subsequently, bonding a layer of unstrained semiconductor material to an upper surface of said layer of strained insulating material.

6. The method of claim 1, wherein the precursor structure is formed by: (a) providing a layer of unstrained insulating material supported by a semiconductor substrate; (b) bonding a layer of unstrained semiconductor material to an upper surface of said layer of unstrained insulating material; and (c) subsequently, generating stress in said layer of unstrained insulating material.

7. The method of claim 6, wherein stress is generated in said layer of unstrained insulating material by a process selected from the group consisting of high temperature annealing, oxidation, and ion implantation.

8. The method of claim 7, wherein stress is generated in said layer of unstrained insulating material by a high temperature annealing process conducted in a temperature range of from about 500° C. to about 1100° C.

9. The method of claim 1, wherein the strained insulating material layers contain compressive stress, the relaxation of which applies tensile strain to the unstrained semiconductor material layers, thereby forming one or more tensilely-strained semiconductor-on-insulator structures.

10. The method of claim 1, wherein the strained insulating material layers contain tensile stress, the relaxation of which applies compressive strain to the unstrained semiconductor material layers, thereby forming one or more compressively-strained semiconductor-on-insulator structures.

11. The method of claim 1, wherein the upper layer of unstrained semiconductor material has a thickness in a range of from about 5 nm to about 200 nm.

12. The method of claim 1, wherein the lower layer of strained insulating material has a thickness in a range of from about 50 nm to about 1 μm.

13. The method of claim 12, wherein said one or more islands has an average diameter in a range of from about 100 nm to about 20 μm.

14. The method of claim 13, wherein the average diameter of said one or more islands is about 5 to 20 times of the thickness of the lower layer of strained insulating material.

15. A precursor structure comprising an upper layer of unstrained semiconductor material and a lower layer of strained insulating material supported by a semiconductor substrate, wherein said upper layer of unstrained semiconductor material and said lower layer of strained insulating material are patterned to form one or more islands that each comprise an unstrained semiconductor material layer overlaying a strained insulating material layer, and wherein relaxation of the strained insulating material layers in said islands applies strain to the unstrained semiconductor material layers, resulting in one or more strained semiconductor-on-insulator structures.

16. The precursor structure of claim 15, wherein said unstrained semiconductor material layer comprises one or more materials selected from the group consisting of Si, SiC, SiGe, SiGeC, Ge, GaAs, InAs, InP, III-V compound semiconductor materials, and II-VI compound semiconductor materials.

17. The precursor structure of claim 15, wherein said strained insulating material layer comprises spin-on glass.

18. The precursor structure of claim 17, wherein the strained insulating material layer contains compressive stress, the relaxation of which applies tensile strain to the unstrained semiconductor material layer, thereby forming one or more tensilely-strained semiconductor-on-insulator structures.

19. The precursor structure of claim 15, wherein the strained insulating material layer has a thickness in a range of from about 50 nm to about 1 μm, wherein said one or more islands has an average diameter in a range of from about 100 nm to about 20 μm, and wherein the average diameter of said one or more islands is about 5 to 20 times of the thickness of the strained insulating material layer.

20. A method for forming a strained semiconductor-on-insulator structure, said method comprising forming an unstrained semiconductor material layer over a strained insulating material layer and subsequently allowing the strained insulating material to at least partially relax, thereby applying strain to said unstrained semiconductor material layer.
